(19) United States
(12) Patent Application Publication
(10) Pub. No.: US 2025/0157867 A1
(43) Pub. Date: May 15, 2025

(54) SEMICONDUCTOR PACKAGE

(71) Applicant: Samsung Electronics Co., Ltd., Suwon-si (KR)

(72) Inventors: Jongkook KIM, Suwon-si (KR); Heungkyu KWON, Suwon-si (KR); Youngchul KIM, Singapore (SG); Choonheung LEE, Singapore (SG); Donghyun CHA, Singapore (SG); Junghwa KIM, Suwon-si (KR); Junso PAK, Suwon-si (KR); Kyounghoon LEE, Singapore (SG); Jaegwon JANG, Suwon-si (KR); Hangchul CHOI, Singapore (SG); Heejung CHOI, Suwon-si (KR); Kyojin HWANG, Suwon-si (KR)

(73) Assignees: Samsung Electronics Co., Ltd., Suwon-si (KR); STATS ChipPAC Pte. Ltd., Singapore (SG)

(21) Appl. No.: 18/883,053

(22) Filed: Sep. 12, 2024

(30) Foreign Application Priority Data
Nov. 10, 2023 (SG) 10202303199U

(51) Int. Cl. H01L 23/16; H01L 23/00; H01L 23/31; H01L 23/367; H01L 25/18; H05K 1/18; H10B 80/00

(52) U.S. Cl. CPC H01L 23/16; H01L 23/3135; H01L 23/3677; H01L 24/06; H01L 24/08; H05K 1/181; H01L 25/18; H01L 2224/06131; H01L 2224/08225; H01L 2924/1431; H01L 2924/19011; H10B 80/00

(57) ABSTRACT

A semiconductor package that includes an upper package including a first package substrate, a first semiconductor chip mounted on the first package substrate, and a first molding layer surrounding the first semiconductor chip; a printed circuit board (PCB) on which the upper package is mounted in a central region; and a stiffener positioned on a top surface of the PCB and including an opening. A top surface of the PCB contacts a bottom surface of the stiffener in at least part of edge regions of the PCB. In the central region of the PCB and in edge regions other than the at least part of edge regions of the PCB, a top surface of the PCB is apart from the bottom surface of the stiffener in a vertical direction, and the opening of the stiffener overlaps the upper package in the vertical direction.

### CROSS-REFERENCE TO RELATED APPLICATION

This application is based on and claims priority under 35 U.S.C. § 119 to Singapore patent application Ser. No. 10/202,303199U, filed on Nov. 10, 2023, in the Intellectual Property Office of SINGAPORE, the disclosure of which is incorporated by reference herein in its entirety.

### BACKGROUND

The inventive concepts relate to a semiconductor packages, and more particularly to semiconductor packages including a stiffener.

A semiconductor package may include a semiconductor chip implemented in a form suitable for use in electronic products. Typically, in the semiconductor package, the semiconductor chip is mounted on a printed circuit board (PCB) and is electrically connected to the PCB by using bonding wires or bumps. As semiconductor packages become faster and have higher capacities, power consumption of the semiconductor packages is increasing. Accordingly, the importance of PCB/package structures that meet the size/performance requirements of semiconductor packages and that provide stable power supply to the semiconductor package is increasing.

### SUMMARY

The present disclosure relates to a semiconductor package with improved heat dissipation performance.

The present disclosure relates to a semiconductor package capable of suppressing a warpage phenomenon.

The present disclosure relates to a miniaturized semiconductor package in which a signal distance between a passive element and a semiconductor chip is reduced.

The problems to be solved by the technical ideas of the inventive concepts are not limited to the above-mentioned problems, and other problems may be clearly understood by those skilled in the art from the description below.

Some example embodiments of the inventive concepts provide a semiconductor package that includes an upper package including a first package substrate, a first semiconductor chip on the first package substrate, and a first molding layer surrounding the first semiconductor chip; a printed circuit board (PCB), the upper package being in a central region of the PCB; and a stiffener on a top surface of the PCB, the stiffener including an opening. The top surface of the PCB contacts a bottom surface of the stiffener in at least part of edge regions of the PCB. In the central region of the PCB and in edge regions other than the part of edge regions of the PCB contacting the stiffener, the top surface of the PCB is apart from the bottom surface of the stiffener in a vertical direction. The opening of the stiffener overlaps the upper package in a vertical direction.

Some example embodiments of the inventive concepts further provides a semiconductor package that includes a first upper package including a first package substrate, a first semiconductor chip on the first package substrate, and a first molding layer surrounding the first semiconductor chip; a plurality of second upper packages each including a second package substrate, a second semiconductor chip on the second package substrate, and a second molding layer surrounding the second semiconductor chip; a printed circuit board (PCB), the first upper package being mounted on a central region of the PCB, and the PCB electrically connects the first upper package to the plurality of second upper packages; and a stiffener on a top surface of the PCB, the stiffener including an opening. At least some part of edge regions of the PCB contact the stiffener. The central region of the PCB and edge regions other than the part of edge regions of the PCB contacting the stiffener are apart from the stiffener in a vertical direction. The opening of the stiffener overlaps the first upper package in the vertical direction.

Some example embodiments of the inventive concepts still further provide a semiconductor package that includes a first upper package including a first package substrate, a first semiconductor chip on the first package substrate, and a first molding layer surrounding side surfaces of the first semiconductor chip, the first semiconductor chip having a horizontal area less than a horizontal area of the first package substrate; a printed circuit board (PCB), the upper package being on a central region of the PCB, and the PCB has a horizontal area greater than a horizontal area of the first upper package; and a stiffener attached to a top surface of the PCB by an adhesive layer, the stiffener including an opening. A pitch between each two of a plurality of lower connection pads of the first semiconductor chip is less than a pitch between each two of a plurality of lower connection terminals of the first package substrate. The pitch between each two of the plurality of lower connection terminals of the first package substrate is less than a pitch between each two of a plurality of lower connection terminals of the PCB. The top surface of the PCB contacts a bottom surface of the stiffener in at least part of edge regions of the PCB. In the central region of the PCB and in edge regions other than the part of edge regions of the PCB contacting the stiffener, the top surface of the PCB is apart from the bottom surface of the stiffener in a vertical direction. The opening of the stiffener overlaps the first upper package in a vertical direction.

### BRIEF DESCRIPTION OF THE DRAWINGS

Some example embodiments of the inventive concepts will be more clearly understood from the following detailed description taken in conjunction with the accompanying drawings in which:

FIG. 1 is a perspective view schematically illustrating a semiconductor package according to some example embodiments;

FIG. 2 is a plan view schematically illustrating the semiconductor package of FIG. 1;

FIG. 3 is a plan view schematically illustrating a printed circuit board (PCB) of the semiconductor package of FIG. 2;

FIG. 4 is a cross-sectional view schematically illustrating the semiconductor package of FIG. 2 taken along the line A1-A1′ of FIG. 2;

FIG. 5 is a cross-sectional view schematically illustrating the semiconductor package of FIG. 2 taken along the line B1-B1′ of FIG. 2;

FIG. 6 is a plan view schematically illustrating a semiconductor package according to some example embodiments;

FIG. 7 is a cross-sectional view schematically illustrating the semiconductor package of FIG. 6 taken along the line A2-A2′ of FIG. 6;

FIG. 8 is a cross-sectional view schematically illustrating the semiconductor package of FIG. 6 taken along the line B2-B2′ of FIG. 6;

FIG. 9 is a plan view schematically illustrating a semiconductor package according to some example embodiments;

FIG. 10 is a cross-sectional view schematically illustrating the semiconductor package of FIG. 9 taken along the line A3-A3′ of FIG. 9;

FIG. 11 is a cross-sectional view schematically illustrating the semiconductor package of FIG. 9 taken along the line B3-B3′ of FIG. 9;

FIG. 12 is a plan view schematically illustrating a semiconductor package according to some example embodiments;

FIG. 13 is a cross-sectional view schematically illustrating the semiconductor package of FIG. 12 taken along the line A4-A4′ of FIG. 12;

FIG. 14 is a perspective view schematically illustrating a semiconductor package according to some example embodiments;

FIG. 15 is a plan view schematically illustrating the semiconductor package of FIG. 14;

FIG. 16 is a cross-sectional view schematically illustrating the semiconductor package of FIG. 15 taken along the line C-C′ of FIG. 15;

FIG. 17 is a cross-sectional view schematically illustrating the semiconductor package of FIG. 15 taken along the line D-D′ of FIG. 15;

FIGS. 18, 19 and 20 are cross-sectional views schematically illustrating semiconductor packages according to some example embodiments, each taken along the line C-C′ of FIG. 14; and

FIGS. 21 and 22 are cross-sectional views schematically illustrating semiconductor packages according to some example embodiments, each taken along the line C-C′ of FIG. 14.

### DETAILED DESCRIPTION

Because current example embodiments may be subject to various changes and have various forms, some example embodiments will be illustrated in the drawings and described in detail. However, the example embodiments are not limited to a specific disclosure form.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

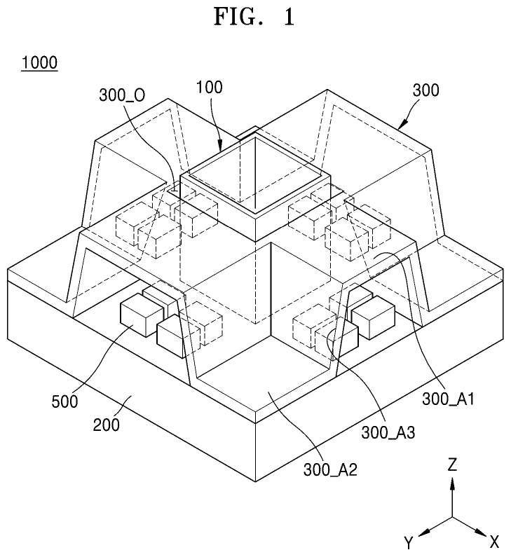

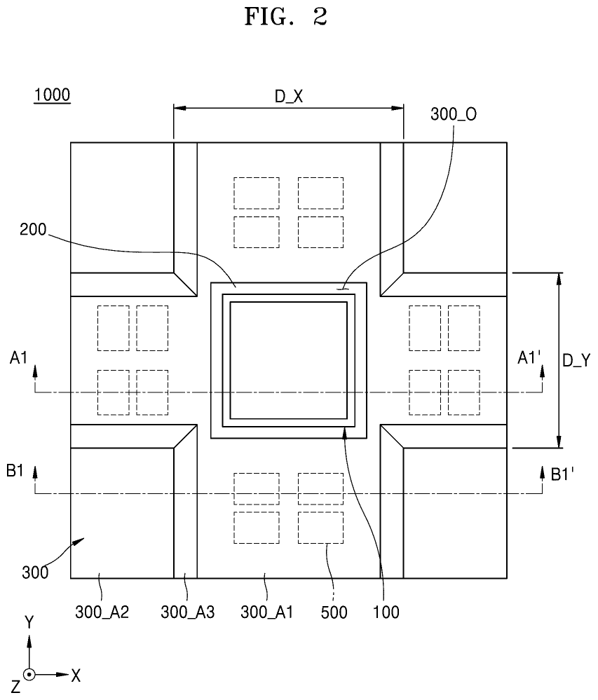

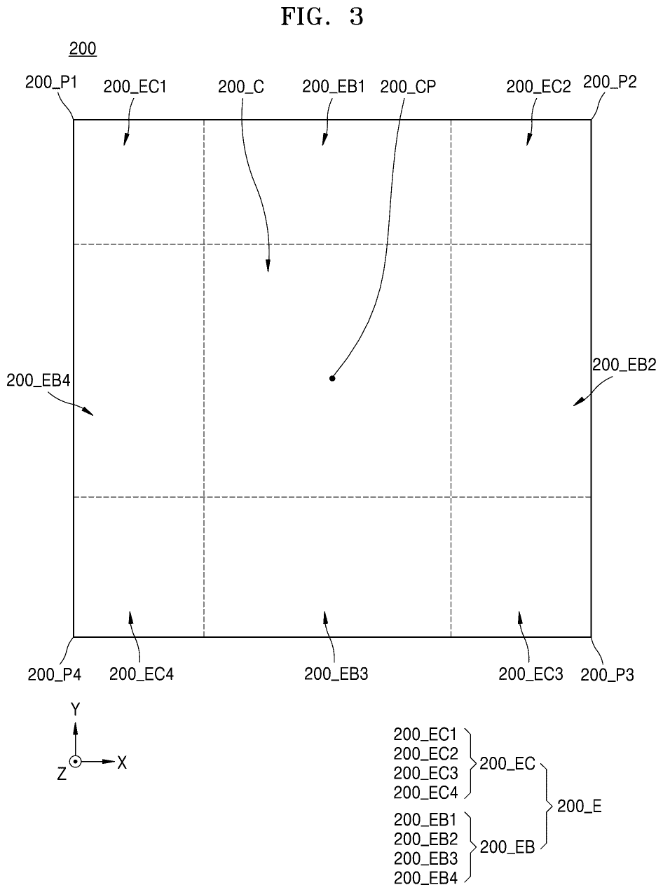

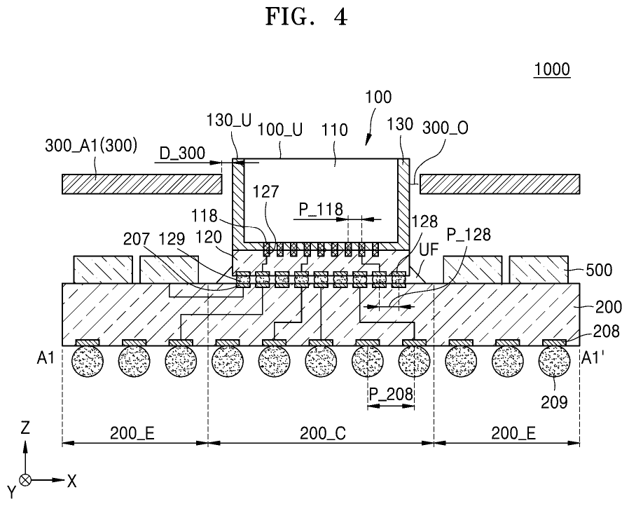

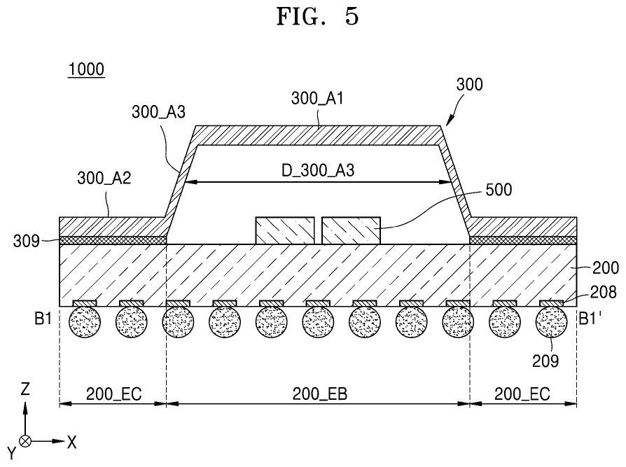

FIG. 1 is a perspective view schematically illustrating a semiconductor package 1000 according to some example embodiments. FIG. 2 is a plan view schematically illustrating the semiconductor package 1000 of FIG. 1. FIG. 3 is a plan view schematically illustrating a printed circuit board (PCB) 200 of the semiconductor package 1000 of FIG. 2. FIG. 4 is a cross-sectional view schematically illustrating the semiconductor package 1000 of FIG. 2 taken along the line A1-A1′ of FIG. 2. FIG. 5 is a cross-sectional view schematically illustrating the semiconductor package 1000 of FIG. 2 taken along the line B1-B1′ of FIG. 2.

Referring to FIGS. 1 to 5, the semiconductor package 1000 may include the PCB 200, a first upper package 100, and a stiffener 300. In some example embodiments, the semiconductor package 1000 may further include a plurality of passive elements 500.

The PCB 200 of the semiconductor package 1000 may include, for example, a module board on which a package is mounted. For example, the PCB 200 may correspond to a thin core high density interconnect (HDI) PCB.

The PCB 200 may generally have a flat plate or panel shape. The PCB 200 may include top and bottom surfaces opposite to each other, and the top and bottom surfaces may be flat surfaces, respectively. Hereinafter, a horizontal direction (for example, an X direction and/or a Y direction) may be defined as a direction parallel to the top surface of the PCB 200, and a vertical direction (for example a Z direction) may be defined as a direction perpendicular to the top surface of the PCB 200.

The PCB 200 may include a core insulating layer, a plurality of upper connection pads 207, and a plurality of lower connection pads 208.

The core insulating layer may include at least one material selected from phenol resin, epoxy resin, and polyimide. For example, the core insulating layer may include at least one material selected from polyimide, flame retardant (FR)-4, tetrafunctional epoxy, polyphenylene ether, epoxy/polyphenylene oxide, bismaleimide triazine (BT), THERMOUNT® (a nonwoven aramid fiber reinforced substrate for printed wiring boards), cyanate ester, and liquid crystal polymer.

The plurality of upper connection pads 207 may be provided on a top surface of the core insulating layer. Conductive connection members for electrical and physical connection between the PCB 200 and mounting parts mounted on the PCB 200 may be attached to the plurality of upper connection pads 207.

The plurality of lower connection pads 208 may be provided on a bottom surface of the core insulating layer. External connection terminals 209 may be attached to the plurality of lower connection pads 208. The external connection terminals 209 may electrically and physically connect the PCB 200 to an external device on which the PCB 200 is mounted. The external connection terminals 209 may include, for example, solder balls or solder bumps. The plurality of upper connection pads 207 may be electrically connected to the plurality of lower connection pads 208 by a metal wiring structure provided in the core insulating layer.

For example, the plurality of upper connection pads 207 and the plurality of lower connection pads 208 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof.

As illustrated in FIG. 3, the PCB 200 may include a central region 200_C and an edge region 200_E. The central region 200_C may include a central point 200_CP of the top surface of the printed circuit board 200, and the edge region 200_E may be a region surrounding the central region 200_C. The edge region 200_E may include first to fourth vertices 200_P1, 200_P2, 200_P3, and 200_P4 of the top surface of the PCB 200. That is, the edge region 200_E may extend from one end of the central region 200_C to one end of the PCB 200.

The edge region 200_E of the PCB 200 may include a corner region 200_EC and an intermediate region 200_EB between adjacent corner regions.

For example, the edge region 200_E may include first to fourth corner regions 200_EC1, 200_EC2, 200_EC3, and 200_EC4 corresponding to the first to fourth vertices 200_P1, 200_P2, 200_P3, and 200_P4 of the top surface of the PCB 200. The first corner region 200_EC1 may be apart from the second corner region 200_EC2 in a first horizontal direction (X direction), the second corner region 200_EC2 may be apart from the third corner region 200_EC3 in a second horizontal direction (Y direction), the third corner region 200_EC3 may be apart from the fourth corner region 200_EC4 in the first horizontal direction (X direction), and the fourth corner region 200_EC4 may be apart from the first corner region 200_EC1 in the second horizontal direction (Y direction).

The intermediate region 200_EB may include a first intermediate region 200_EB1 between the first corner region 200_EC1 and the second corner region 200_EC2, a second intermediate region 200_EB2 between the second corner region 200_EC2 and the third corner region 200_EC3, a third intermediate region 200_EB3 between the third corner region 200_EC3 and the fourth corner region 200_EC4, and a fourth intermediate region 200_EB4 between the fourth corner region 200_EC4 and the first corner region 200_EC1.

The first upper package 100 of the semiconductor package 1000 may include a first package substrate 120, a first semiconductor chip 110, and a first molding layer 130.

The first upper package 100 may be mounted on the PCB 200. A horizontal area of the first upper package 100 may be less than a horizontal area of the PCB 200. For example, the first upper package 100 may be mounted in the central region 200_C of the PCB 200. In some example embodiments, the central point 200_CP of the top surface of the PCB 200 and the central point of a top surface of the first upper package 100 may be straight in the vertical direction (Z direction). For example, the central point 200_CP may be aligned with the central point of the top surface of the first upper package 100 along the vertical direction (z direction).

Like the PCB 200, the first package substrate 120 of the first upper package 100 may include a core insulating layer, a plurality of upper connection pads 127, and a plurality of lower connection pads 128. According to some example embodiments, the first package substrate 120 may be thinner than the PCB 200. The plurality of upper connection pads 127 may be electrically connected to the plurality of lower connection pads 128 by a metal wiring structure provided in the core insulating layer.

The plurality of upper connection pads 127 may be provided on the top surface of the core insulating layer. The plurality of upper connection pads 127 may be electrically and physically connected to a plurality of lower connection pads 118 of the first semiconductor chip 110 mounted on the first package substrate 120. For example, the plurality of upper connection pads 127 of the first package substrate 120 may correspond one-to-one to the plurality of lower connection pads 118 of the first semiconductor chip 110.

The plurality of lower connection pads 128 may be provided on the bottom surface of the core insulating layer. The plurality of lower connection pads 128 may be electrically and physically connected to the plurality of upper connection pads 207 of the PCB 200 by conductive connection members 129. The conductive connection members 129 may include, for example, solder balls or solder bumps. For example, the plurality of lower connection pads 128 of the first package substrate 120 may correspond one-to-one to the plurality of upper connection pads 207 of the PCB 200. An underfill UF may be filled between the first package substrate 120 and the PCB 200 and between the conductive connection members 129.

Hereinafter, “pitch” means a distance between centers of pads adjacent to each other in the horizontal direction.

In some example embodiments, a pitch P_208 between each two of the plurality of lower connection pads 208 of the PCB 200, a pitch P_128 between each two of the plurality of lower connection pads 128 of the first package substrate 120, and a pitch P_118 between each two of the plurality of lower connection pads 118 of the first semiconductor chip 110 may be different from one another. For example, the pitch P_208 between each two of the plurality of lower connection pads 208 of the PCB 200 may be greater than the pitch P_128 between each two of the plurality of lower connection pads 128 of the first package substrate 120, and the pitch P_128 between each two of the plurality of lower connection pads 128 of the first package substrate 120 may be greater than the pitch P_118 between each two of the plurality of lower connection pads 118 of the first semiconductor chip 110. In some example embodiments, the pitch P_208 between each two of the plurality of lower connection pads 208 of the PCB 200 may be 0.8 mm to 1.3 mm, the pitch P_128 between each two of the plurality of lower connection pads 128 of the first package substrate 120 may be 0.3 mm to 0.6 mm, and the pitch P_118 between each two of the plurality of lower connection pads 118 of the first semiconductor chip 110 may be 0.1 mm to 0.2 mm.

The first semiconductor chip 110 of the first upper package 100 may be mounted on the first package substrate 120. A horizontal area of the first semiconductor chip 110 may be less than a horizontal area of the first package substrate 120.

In some example embodiments, the first semiconductor chip 110 may be mounted on the first package substrate 120 by a flip-chip method. For example, the plurality of lower connection pads 118 of the first semiconductor chip 110 may be electrically connected to the plurality of upper connection pads 127 of the first package substrate 120, respectively.

In some example embodiments, the first semiconductor chip 110 may include a system on chip (SOC) or a logic chip. Here, the logic chip may include an application processor (AP), a microprocessor, a central processing unit (CPU), a graphics processing unit (GPU), a neural processing unit (NPU), a controller, or an application specific integrated circuit (ASIC).

For example, the first semiconductor chip 110 as an advanced RISC machine (ARM) server SOC may include a dynamic random access memory (DRAM) interface (I/F) for a dual in-line memory module (DIMM), a peripheral component interconnect express (PCIe) I/F serving as a switch, and a CPU.

The first molding layer 130 of the first upper package 100 may surround side surfaces of the first semiconductor chip 110 and may cover a top surface of the first package substrate 120. Sidewalls of the first molding layer 130 may be aligned with sidewalls of the first package substrate 120 in the vertical direction (Z direction) to be coplanar. The first molding layer 130 may include, for example, an epoxy mold compound (EMC).

The first molding layer 130 may protect the first semiconductor chip 110 against the outside. However, the first molding layer 130 may not cover a top surface of the first semiconductor chip 110. A top surface of the first semiconductor chip 110 may be exposed to the outside, so that heat generated by the first semiconductor chip 110 may be easily dissipated. In some example embodiments, the top surface of the first semiconductor chip 110 may be aligned with a top surface 130_U of the first molding layer 130 in the horizontal direction to be coplanar. That is, a vertical level of the first semiconductor chip 110 may be the same as a vertical level of the first molding layer 130. In the current specification, the “vertical level” means a distance from the bottom surface of the PCB 200.

The stiffener 300 of the semiconductor package 1000 may be positioned on the PCB 200. The stiffener 300 may have a curved shape, for example, may include regions having different vertical levels. In some example embodiments, the stiffener 300 may include contact units (e.g., members) 300_A2, separation units (e.g., members) 300_A1, and extension (e.g., members) 300_A3. At the contact units 300_A2, a bottom surface of the stiffener 300 contacts the top surface of the PCB 200, at the separation units 300_A1, the bottom surface of the stiffener 300 is apart from the top surface of the PCB 200, and, at the extension units 300_A3, the contact units 300_A2 are connected to the separation units 300_A1.

For example, the contact units 300_A2 and the separation units 300_A1 may be parallel to the top surface of the PCB 200, and a vertical level of each of the contact units 300_A2 may be different from a vertical level of each of the separation units 300_A1. For example, the vertical level of each of the contact units 300_A2 may be lower than the vertical level of each of the separation units 300_A1.

The extension units 300_A3 may be inclined in the vertical direction (Z direction) with respect to the top surface of the PCB 200 to connect the contact units 300_A2 and the separation units 300_A1 having different vertical levels. Referring to FIG. 5, as the extension units 300_A3 positioned in the same intermediate region among the first to fourth intermediate regions 200_EB1, 200_EB2, 200_EB3, and 200_EB4 and apart from each other in the horizontal direction are farther from the PCB 200, a distance D_300_A3 between the extension units 300_A3 may be reduced. However, when the extension units 300_A3 extend in the vertical direction (Z direction), the distance D_300_A3 between the extension units 300_A3 positioned in the same intermediate region and apart from each other in the horizontal direction may be constant.

A shape of the stiffener 300 will be described in detail based on a contact position between the PCB 200 and the stiffener 300.

In at least a part (e.g., some) of the edge region 200_E of the PCB 200, the top surface of the PCB 200 may contact the bottom surface of the stiffener 300. In the rest of the edge region 200_E and the central region 200_C of the PCB 200, the top surface of the PCB 200 may be apart from the bottom surface of the stiffener 300 in the vertical direction.

In some example embodiments, a region in which the top surface of the PCB 200 contacts the bottom surface of the stiffener 300 may be point symmetrical with respect to the central point 200_CP of the top surface of the PCB 200. That is, the stiffener 300 contacts the PCB 200 to be symmetrical about the central point 200_CP of the top surface of the PCB 200 so that it is possible to suppress a phenomenon in which some regions of the stiffener 300 experience greater stress than other regions.

In some example embodiments, the contact units 300_A2 of the stiffener 300 may be positioned on the corner region 200_EC of the edge region 200_E of the PCB 200. That is, the stiffener 300 may contact the top surface of the PCB 200 near the first to fourth vertices 200_P1, 200_P2, 200_P3, and 200_P4 of the top surface of the PCB 200.

The separation units 300_A1 and the extension units 300_A3 of the stiffener 300 may be positioned on the intermediate region 200_EB of the edge region 200_E of the PCB 200. That is, in the intermediate region 200_EB of the edge region 200_E of the PCB 200, the stiffener 300 may be apart from the PCB 200 in the vertical direction.

For example, the separation units 300_A1 and the extension units 300_A3 of the stiffener 300 may be arranged in a “+” shape in a plan view, and the contact units 300_A2 of the stiffener 300 may include square shapes including the first to fourth vertices 200_P1, 200_P2, 200_P3, and 200_P4 of the top surface of the PCB 200, respectively.

In some example embodiments, the contact units 300_A2 may be apart from each other by a first distance D_X in the first horizontal direction (X direction). The contact units 300_A2 may be apart from each other by a second distance D_Y in the second horizontal direction (Y direction). For example, the first distance D_X may be different from the second distance D_Y.

In some example embodiments, the contact unit 300_A2 positioned on the first corner region 200_EC1 may be apart from the contact unit 300_A2 positioned on the second corner region 200_EC2 by the first distance D_X, and the contact unit 300_A2 positioned on the second corner region 200_EC2 may be apart from the contact unit 300_A2 positioned on the third corner region 200_EC3 by the second distance D_Y different from the first distance D_X.

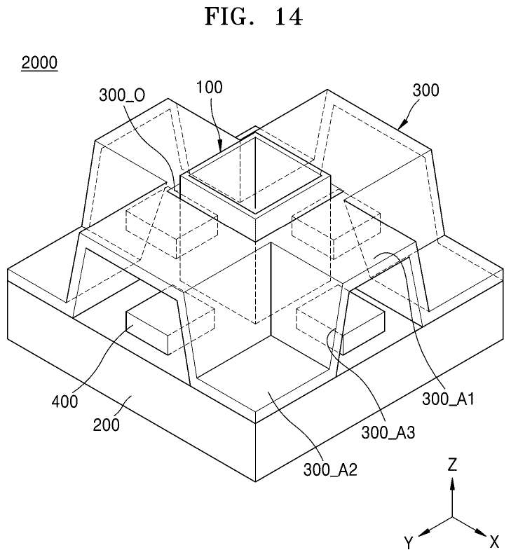

Accordingly, a horizontal area of a space in which the PCB 200 is apart from the stiffener 300 between the first corner region 200_EC1 and the second corner region 200_EC2 is different from a horizontal area of a space in which the PCB 200 is apart from the stiffener 300 between the second corner region 200_EC2 and the third corner region 200_EC3 so that parts mounted in the space in which the PCB 200 is apart from the stiffener 300 between the first corner region 200_EC1 and the second corner region 200_EC2 may be different from parts mounted in the space in which the PCB 200 is apart from the stiffener 300 between the second corner region 200_EC2 and the third corner region 200_EC3. For example, the mounted parts may include a plurality of passive elements 500 or a second upper package 400 of FIG. 14 to be described later.

For example, the number of parts mounted between the contact unit 300_A2 positioned on the first corner region 200_EC1 and the contact unit 300_A2 positioned on the second corner region 200_EC2 may be different from the number of parts mounted between the contact unit 300_A2 positioned on the second corner region 200_EC2 and the contact unit 300_A2 positioned on the third corner region 200_EC3.

The stiffener 300 may include an opening 300_O extending from the top surface thereof to the bottom surface thereof. An upper portion of the PCB 200 may be covered with the stiffener 300 except for a region in which the opening 300_O is positioned. That is, the stiffener 300 may be positioned above a region of the PCB 200 except for the region in which the opening 300_O is positioned. The stiffener 300 may be positioned above the PCB 200 in the region except for the opening 300_O to suppress a warpage phenomenon of the PCB 200.

The first upper package 100 may be positioned in the opening 300_O of the stiffener 300. For example, the first upper package 100 may be mounted on a region of the PCB 200 in which the opening 300_O is positioned.

In some example embodiments, a horizontal area of the opening 300_O may be greater than the horizontal area of the first upper package 100. Side surfaces of the stiffener 300 defining the opening 300_O may be apart from side surfaces of the first upper package 100 in the horizontal direction. For example, a distance D_300 between each of the side surfaces of the stiffener 300 defining the opening 300_O and each of the side surfaces of the first upper package 100 may be 2 mm to 5 mm.

The top surface of the first upper package 100 may be exposed to the outside by the opening 300_O of the stiffener 300. Accordingly, heat generated by the first semiconductor chip 110 of the first upper package 100 may be easily dissipated to the outside.

The stiffener 300 may include a metal such as steel or copper (Cu). However, a material of the stiffener 300 is not limited thereto. The stiffener 300 may be adhered and fixed to the PCB 200 through an adhesive layer 309.

The plurality of passive elements 500 of the semiconductor package 1000 may be mounted on the PCB 200. The plurality of passive elements 500 may be positioned below the separation units 300_A1 and the extension units 300_A3 of the stiffener 300. For example, the plurality of passive elements 500 may be positioned on the top surface of the PCB 200 in regions in which the PCB 200 is apart from the stiffener 300 in the vertical direction. In some example embodiments, an air gap may be formed between the plurality of passive elements 500 and the bottom surface of the stiffener 300. The plurality of passive elements 500 may include, for example, one of an inductor, a resistor, and a capacitor. It is illustrated in FIG. 2 that four passive elements 500 are arranged on each side of the first upper package 100. However, the number and positions of passive elements 500 are not limited thereto.

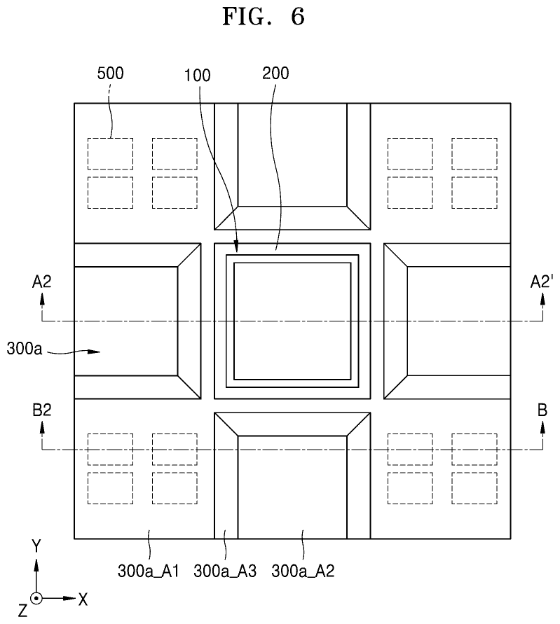

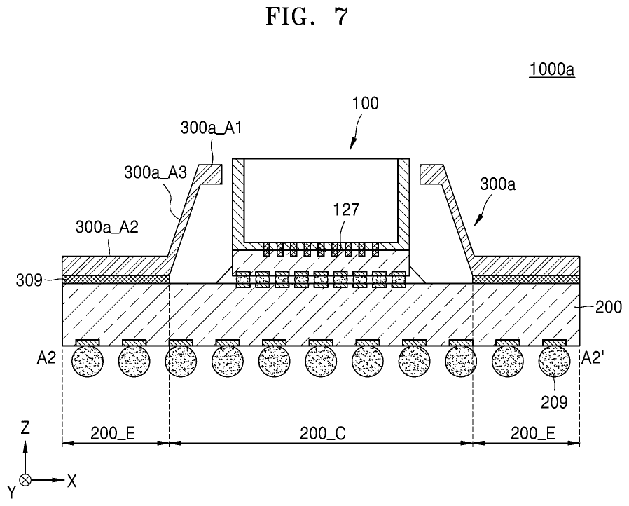

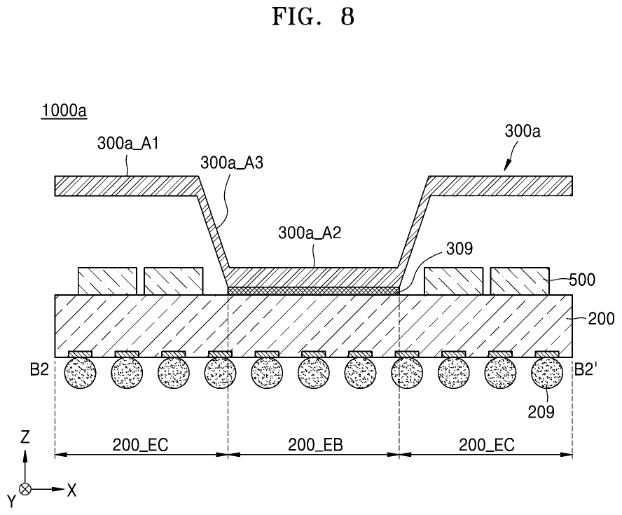

FIG. 6 is a plan view schematically illustrating a semiconductor package 1000a according to some example embodiments. FIG. 7 is a cross-sectional view schematically illustrating the semiconductor package 1000a of FIG. 6 taken along the line A2-A2′ of FIG. 6. FIG. 8 is a cross-sectional view schematically illustrating the semiconductor package 1000a of FIG. 6 taken along the line B2-B2′ of FIG. 6.

Most of components constituting the semiconductor package 1000a described below and materials forming the components are the same or substantially the same as or similar to those previously described in FIG. 1. Therefore, for convenience sake, differences between the semiconductor package 1000a of FIG. 6 and the semiconductor package 1000 of FIG. 1 described above will be mainly described.

A stiffener 300a of the semiconductor package 1000a may be positioned on a PCB 200. The stiffener 300a may have a curved shape, for example, may include regions having different vertical levels. In some example embodiments, the stiffener 300a may include contact units 300a_A2, separation units 300a_A1, and extension units 300a_A3. In the contact units 300a_A2, a bottom surface of the stiffener 300a contacts a top surface of the PCB 200, in the separation units 300a_A1, the bottom surface of the stiffener 300a is apart from the top surface of the PCB 200, and, in the extension units 300a_A3, the contact units 300a_A2 are connected to the separation units 300a_A1.

The separation units 300a_A1 and the extension units 300a_A3 of the stiffener 300a may be positioned on a corner region 200_EC of an edge region 200_E of the PCB 200. That is, the stiffener 300a may be apart from the PCB 200 near first to fourth vertices 200_P1, 200_P2, 200_P3, and 200_P4 of the top surface of the PCB 200.

The contact units 300a_A2 of the stiffener 300a may be positioned on an intermediate region 200_EB of the edge region 200_E of the PCB 200. That is, in the intermediate region 200_EB of the edge region 200_E of the PCB 200, the stiffener 300a may contact the PCB 200.

For example, the stiffener 300a may contact the PCB 200 in a square shape near the center of each side of the top surface of the PCB 200, and may be apart from the PCB 200 in the vertical direction (Z direction) in the other regions. The separation units 300a_A1 and the extension units 300a_A3 may be arranged in an “X” shape.

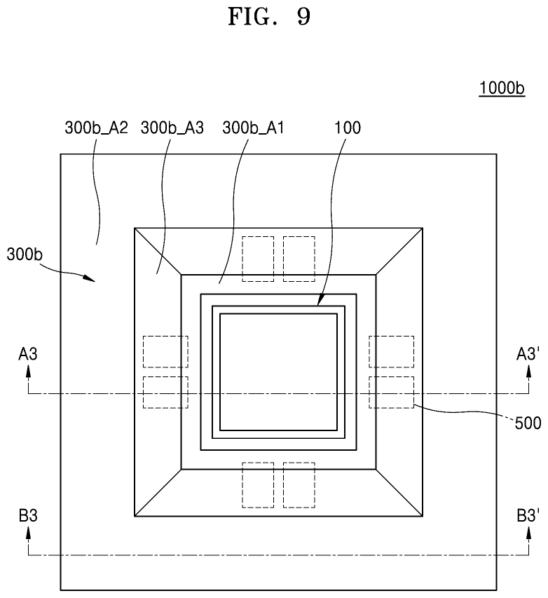

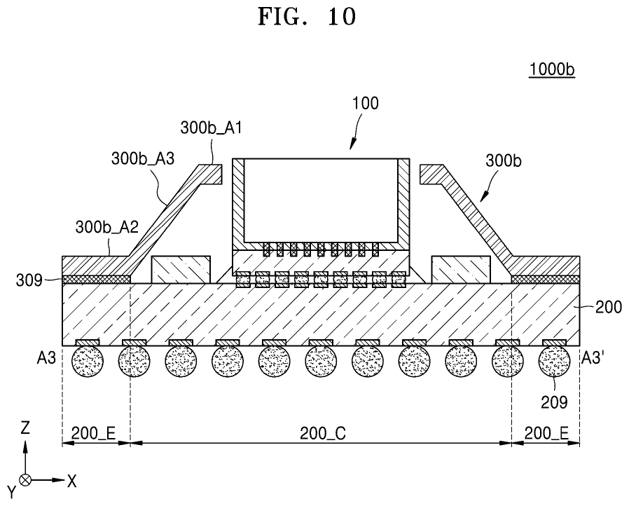

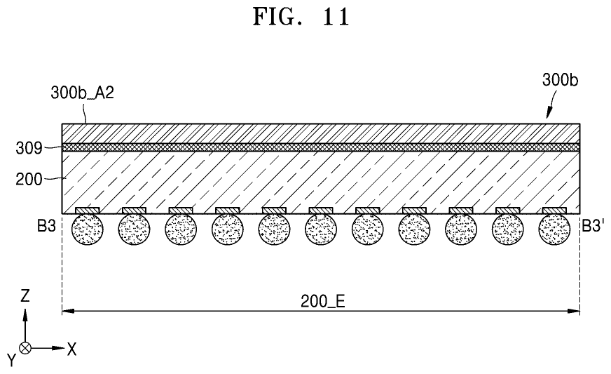

FIG. 9 is a plan view schematically illustrating a semiconductor package 1000b according to some example embodiments. FIG. 10 is a cross-sectional view schematically illustrating the semiconductor package 1000b of FIG. 9 taken along the line A3-A3′ of FIG. 9. FIG. 11 is a cross-sectional view schematically illustrating the semiconductor package 1000b of FIG. 9 taken along the line B3-B3′ of FIG. 9.

Most of components constituting the semiconductor package 1000b described below and materials forming the components are the same or substantially the same as or similar to those previously described in FIG. 1. Therefore, for convenience sake, differences between the semiconductor package 1000b of FIG. 9 and the semiconductor package 1000 of FIG. 1 described above will be mainly described.

A stiffener 300b of the semiconductor package 1000b may be positioned on a PCB 200. The stiffener 300b may have a curved shape, for example, may include regions having different vertical levels. In some example embodiments, the stiffener 300b may include a contact unit 300b_A2, a separation unit 300b_A1, and an extension unit 300b_A3.

The contact unit 300b_A2 of the stiffener 300b may be positioned on an edge region 200_E of the PCB 200. The contact unit 300b_A2 may extend along an edge of the top surface of the PCB 200. For example, the contact unit 300b_A2 may have a square ring shape. That is, near the edge of the top surface of the PCB 200, the stiffener 300b may contact the PCB 200.

The separation unit 300b_A1 and the extension unit 300b_A3 of the stiffener 300b may be positioned on a central region 200_C of the PCB 200. That is, in the central region 200_C of the PCB 200, the stiffener 300b may be apart from the PCB 200 in the vertical direction (Z direction). The separation unit 300b_A1 and the extension unit 300b_A3 may be arranged in a square shape. The passive elements 500 may be arranged for example in the central region 200_C of the PCB 200 under extension units 300b_A3.

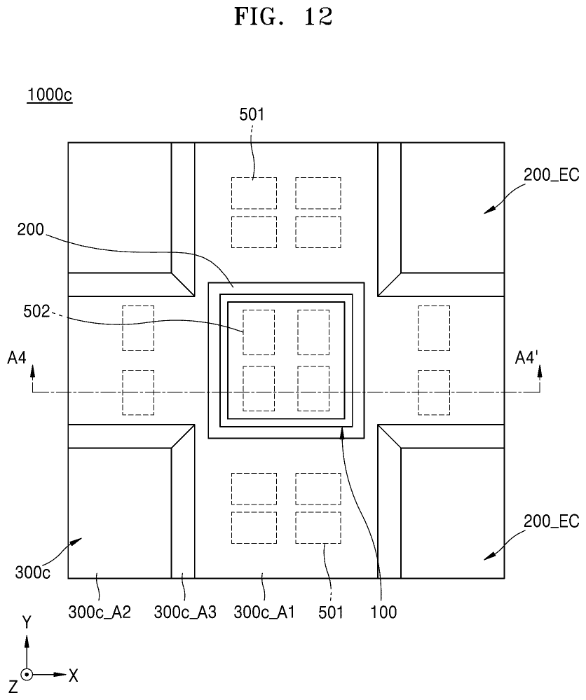

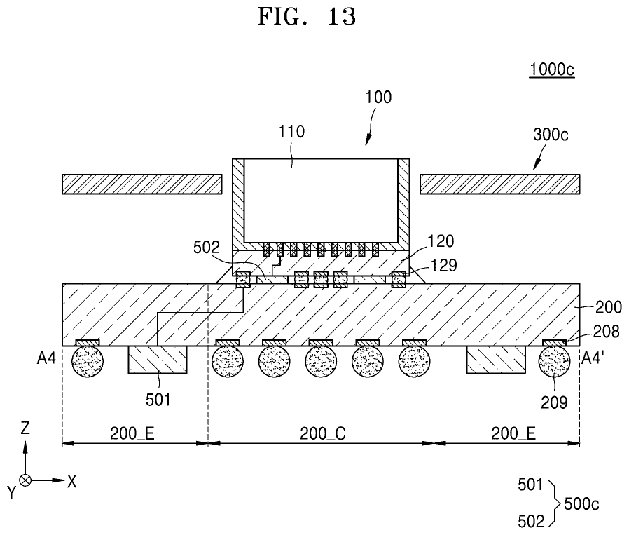

FIG. 12 is a plan view schematically illustrating a semiconductor package 1000c according to some example embodiments. FIG. 13 is a cross-sectional view schematically illustrating the semiconductor package 1000c of FIG. 12 taken along the line A4-A4′ of FIG. 12.

Most of components constituting the semiconductor package 1000c described below and materials forming the components are the same or substantially the same as or similar to those previously described in FIG. 1. Therefore, for convenience sake, differences between the semiconductor package 1000c of FIG. 12 and the semiconductor package 1000 of FIG. 1 described above will be mainly described.

The semiconductor package 1000c may further include a plurality of passive elements 500c. The plurality of passive elements 500c may include, for example, one of an inductor, a resistor, and a capacitor.

The plurality of passive elements 500c may be arranged on at least one of a bottom surface of a first package substrate 120 of a first upper package 100 and a bottom surface of a PCB 200. That is, top surfaces of the plurality of passive elements 500c may contact the bottom surface of the first package substrate 120 or the bottom surface of the PCB 200.

The plurality of passive elements 500c may include first passive elements 501 and second passive elements 502, respectively. The first passive elements 501 may be mounted on the bottom surface of the PCB 200, and the second passive elements 502 may be mounted on the bottom surface of the first package substrate 120. For example, parts may not be mounted on a region of the top surface of the PCB 200 in which the stiffener 300c is apart from the PCB 200 in the vertical direction. That is, the parts may not be mounted between the separation unit 300c_A1 and the extension unit 300c_A3 of the stiffener 300c and the PCB 200.

The first passive elements 501 may be surrounded by the external connection terminals 209. The external connection terminals 209 positioned on the bottom surface of the PCB 200 may be arranged in a grid structure while surrounding the first passive elements 501. The first passive elements 501 are arranged on the bottom surface of the PCB 200 so that the number of parts mounted on the top surface of the PCB 200 is reduced. Accordingly, a contact area between the stiffener 300c and the PCB 200 may increase. That is, an area of the contact unit 300c_A2 of the stiffener 300c increases so that a warpage phenomenon of the semiconductor package 1000c may be suppressed.

The second passive elements 502 may be positioned between the first package substrate 120 and the PCB 200. For example, the second passive elements 502 may contact the bottom surface of the first package substrate 120. The second passive elements 502 may be surrounded by conductive connection members 129. The conductive connection members 129 positioned on the bottom surface of the first package substrate 120 may be arranged in a grid structure while surrounding the second passive elements 502. The first semiconductor chip 110 may be electrically connected to the second passive elements 502 through the first package substrate 120. A signal distance between the first semiconductor chip 110 and the second passive elements 502 is reduced so that signal integrity (SI) and power integrity (PI) may be improved.

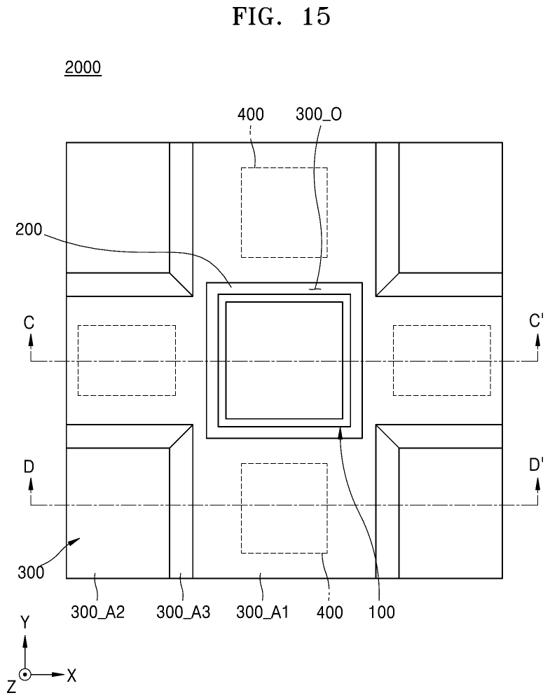

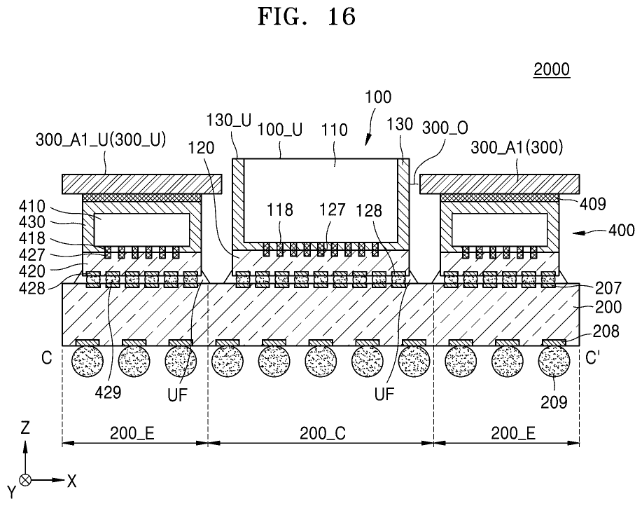

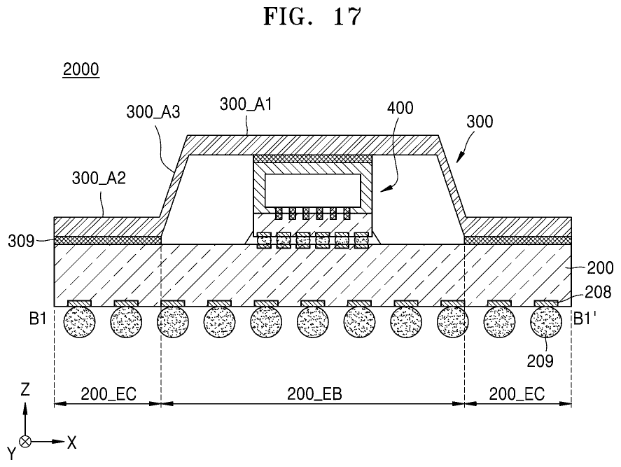

FIG. 14 is a perspective view schematically illustrating a semiconductor package 2000 according to some example embodiments. FIG. 15 is a plan view schematically illustrating the semiconductor package 2000 of FIG. 14. FIG. 16 is a cross-sectional view schematically illustrating the semiconductor package 2000 of FIG. 15 taken along the line C-C′ of FIG. 15. FIG. 17 is a cross-sectional view schematically illustrating the semiconductor package 2000 of FIG. 15 taken along the line D-D′ of FIG. 15.

Referring to FIGS. 14 to 17, the semiconductor package 2000 may include a PCB 200, a first upper package 100, a plurality of second upper packages 400, and a stiffener 300.

Most of components constituting the semiconductor package 2000 described below and materials forming the components are the same or substantially the same as or similar to those previously described in FIG. 1. Therefore, for convenience sake, differences between the semiconductor package 2000 of FIG. 14 and the semiconductor package 1000 of FIG. 1 described above will be mainly described.

The semiconductor package 2000 of FIG. 14 may further include the plurality of second upper packages 400. The plurality of second upper packages 400 may be mounted on the PCB 200. The plurality of second upper packages 400 may be apart from the first upper package 100 in the horizontal direction. In some example embodiments, the plurality of second upper packages 400 may be thinner than the first upper package 100.

Each of the plurality of second upper packages 400 may include a second package substrate 420, a second semiconductor chip 410, and a second molding layer 430.

Like the first package substrate 120, the second package substrate 420 may include a core insulating layer, a plurality of upper connection pads 427, and a plurality of lower connection pads 428. For example, a pitch between each two of the plurality of lower connection pads 428 of the second package substrate 420 may be the same or substantially the same as the pitch between each two of the plurality of lower connection pads 128 of the first package substrate 120.

The plurality of lower connection pads 428 may be electrically and physically connected to the plurality of upper connection pads 207 of the PCB 200 by conductive connection members 429. An underfill UF may be filled between the second package substrate 420 and the PCB 200 and between the conductive connection members 429.

The second semiconductor chip 410 may be mounted on the second package substrate 420. In some example embodiments, the second semiconductor chip 410 may be mounted on the second package substrate 420 by a flip-chip method. For example, the plurality of lower connection pads 418 of the second semiconductor chip 410 may be electrically connected to the plurality of upper connection pads 427 of the second package substrate 420, respectively.

In some example embodiments, the second semiconductor chip 410 may include a memory chip. For example, the memory chip may include dynamic random access memory (DRAM), static random access memory (SRAM), flash memory, electrically erasable and programmable read-only memory (EEPROM), phase-change random access memory (PRAM), magnetic random access memory (MRAM) or resistive random access memory (RRAM) devices.

In some example embodiments, the plurality of second upper packages 400 may include different types of second semiconductor chips. For example, some of the plurality of second upper packages 400 may include memory chips, and others may include power management integrated circuits (PMIC).

A horizontal area of the second semiconductor chip 410 may be less than a horizontal area of the second package substrate 420. The second molding layer 430 may cover a top surface of the second package substrate 420 and may surround the second semiconductor chip 410.

In some example embodiments, the second molding layer 430 may cover a top surface of the second semiconductor chip 410. The second semiconductor chip 410 may be positioned in the second molding layer 430. For example, the second semiconductor chip 410 may be buried in the second molding layer 430.

The plurality of second upper packages 400 may be attached to a bottom surface of the stiffener 300 through an adhesive layer 409. In some example embodiments, the adhesive layer 409 may be positioned on the second molding layer 430 of each of the plurality of second upper packages 400 so that the second molding layer 430 may be attached to the bottom surface of the stiffener 300. By fixing the plurality of second upper packages 400 to the stiffener 300, it is possible to suppress a warpage phenomenon of the semiconductor package 2000 and to suppress a phenomenon in which the plurality of second upper packages 400 are damaged by external force.

The plurality of second upper packages 400 and the first upper package 100 may include different types of semiconductor chips. The first upper package 100 exposed to the outside through an opening 300_O of the stiffener 300 may generate more heat than each of the plurality of second upper packages 400. For example, the plurality of second upper packages 400 may include memory chips and PMICs, and the first upper package 100 may include a logic chip (for example, an SOC chip).

It is illustrated in FIG. 15 that the same number of second upper packages 400 face each edge of the top surface of the PCB 200. However, an arrangement of the plurality of second upper packages 400 is not limited thereto. For example, two or more second upper packages 400 face one edge of the top surface of the PCB 200, and one second upper package 400 faces each of the other edges of the top surface of the PCB 200.

In some example embodiments, when the number of second upper packages 400 facing each edge of the top surface of the PCB 200 varies, a distance D_X or D_Y between contact units 300_A2 of the stiffener 300 near each edge may vary.

The stiffener 300 of the semiconductor package 2000 may include the stiffener 300 of FIG. 2, 300a of FIG. 6, or 300b of FIG. 9 described above. That is, a shape of the stiffener 300 of the semiconductor package 2000 may be a shape of the stiffener 300 of FIG. 2, 300a of FIG. 6, or 300b of FIG. 9 described above. The plurality of second upper packages 400 may be mounted on a region of the top surface of the PCB 200 in which the stiffener 300 is apart from the PCB 200 in the vertical direction. The first upper package 100 may be positioned in the opening 300_O of the stiffener 300. Separation units 300_A1 or extension units 300_A3 of the stiffener 300 may be positioned on the plurality of second upper packages 400, and an upper portion of the first upper package 100 may be exposed to the outside.

In some example embodiments, the uppermost surface 300_A1_U of the stiffener 300 may be at a vertical level different from a vertical level of a top surface 100_U of the first upper package 100. The uppermost surface 300_A1_U of the stiffener 300 is at the highest vertical level in a top surface 300_U of the stiffener 300. For example, the uppermost surface 300_A1_U of the stiffener 300 may be positioned at the separation units 300_A1 of the top surface 300_U of the stiffener 300.

In some example embodiments, the uppermost surface 300_A1_U of the stiffener 300 may be at a vertical level lower than a vertical level of the top surface 100_U of the first upper package 100. Upper ends of side surfaces of the first upper package 100 may protrude in the vertical direction (Z direction) from the uppermost surface 300_A1_U of the stiffener 300 through the opening 300_O.

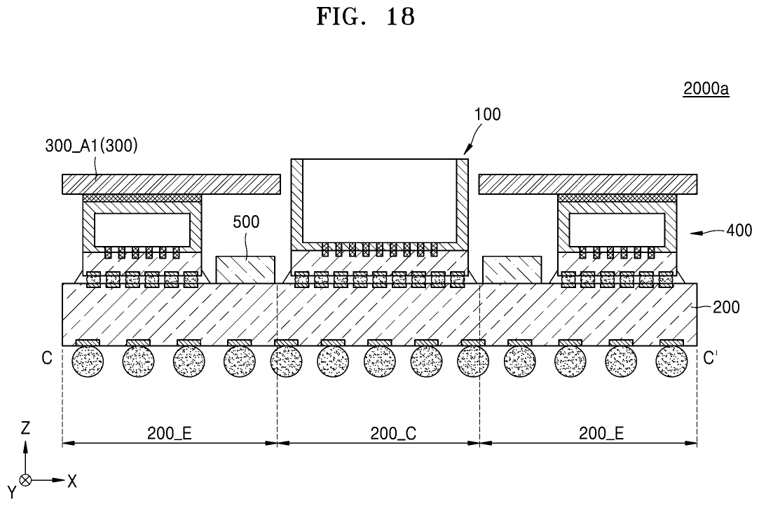

FIGS. 18 to 20 are cross-sectional views schematically illustrating semiconductor packages 2000a, 2000b, and 2000c according to some example embodiments, each taken along the line C-C′ of FIG. 15.

Most of components constituting the semiconductor packages 2000a, 2000b, and 2000c described below and materials forming the components are the same or substantially the same as or similar to those previously described in FIG. 14. Therefore, for convenience sake, differences between the semiconductor packages 2000a, 2000b, and 2000c of FIGS. 18 to 20 and the semiconductor package 2000 of FIG. 14 described above will be mainly described.

Referring to FIG. 18, the semiconductor package 2000a may further include a plurality of passive elements 500. The plurality of passive elements 500 may include, for example, one of an inductor, a resistor, and a capacitor.

The plurality of passive elements 500 may be mounted on a PCB 200. The plurality of passive elements 500 may be positioned below separation units 300_A1 and extension units 300_A3 of a stiffener 300. For example, the plurality of passive elements 500 may be positioned in a space in which the PCB 200 is apart from the stiffener 300 in the vertical direction. In some example embodiments, an air gap may be formed between the plurality of passive elements 500 and a bottom surface of the stiffener 300.

The plurality of passive elements 500 may be apart from a first upper package 100 and a plurality of second upper packages 400 in the horizontal direction. In some example embodiments, the plurality of passive elements 500 may be closer to the plurality of second upper packages 400 than the first upper package 100. In some example embodiments, the plurality of passive elements 500 may be positioned around the plurality of second upper packages 400. In some example embodiments, the plurality of passive elements 500 may be positioned between the first upper package 100 and the plurality of second upper packages 400. However, positions of the plurality of passive elements 500 are not limited thereto.

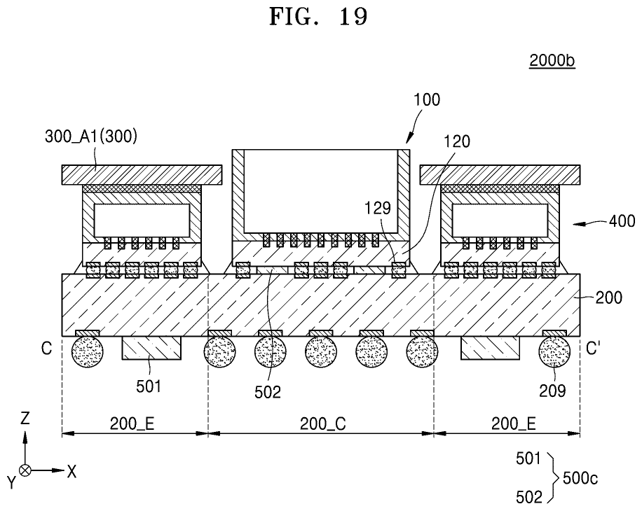

Referring to FIG. 19, the semiconductor package 2000b may further include a plurality of passive elements 500c. The plurality of passive elements 500c may include the plurality of passive elements 500c described with reference to FIG. 13.

The plurality of passive elements 500c may be arranged on at least one of a bottom surface of a first package substrate 120 of a first upper package 100 and a bottom surface of a PCB 200. That is, top surfaces of the plurality of passive elements 500c may contact the bottom surface of the first package substrate 120 or the bottom surface of the PCB 200.

The plurality of passive elements 500c may include first passive elements 501 and second passive elements 502, respectively. The first passive elements 501 may be mounted on the bottom surface of the PCB 200, and the second passive elements 502 may be mounted on the bottom surface of the first package substrate 120. For example, the plurality of passive elements 500c may not be mounted on a region of the top surface of the PCB 200 in which a stiffener 300 is apart from the PCB 200 in the vertical direction.

A contact area between the stiffener 300 and the PCB 200 increases due to the first passive elements 501 so that a warpage phenomenon of the semiconductor package 2000b may be suppressed. A first semiconductor chip 110 may be electrically connected to the second passive elements 502 through the first package substrate 120. A signal distance between the first semiconductor chip 110 and the second passive elements 502 is reduced so that signal integrity (SI) and power integrity (PI) may be improved.

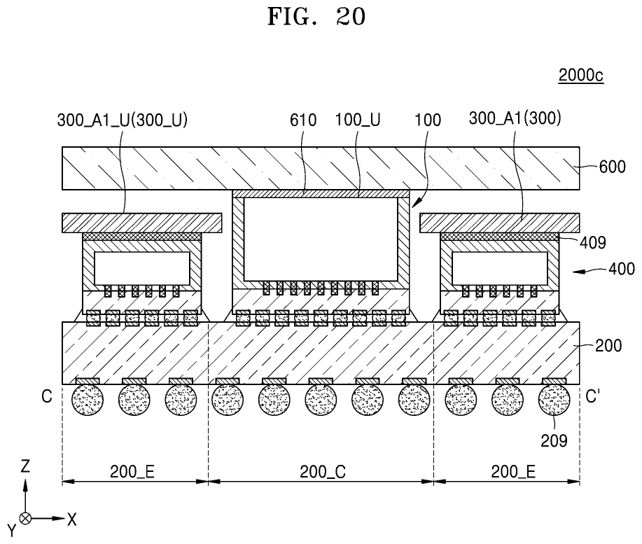

Referring to FIG. 20, the semiconductor package 2000c may further include a heat sink 600.

The heat sink 600 may dissipate heat generated by a semiconductor chip. The heat sink 600 may include a thermally conductive material having high thermal conductivity. For example, the heat sink 600 may include a metal such as copper (Cu) or aluminum (Al), or a carbon-containing material such as graphene, graphite, and/or carbon nanotube. However, a material of the heat sink 600 is not limited thereto. In some example embodiments, the heat sink 600 may include a single metal layer or a plurality of stacked metal layers.

The heat sink 600 may be attached to a first upper package 100. For example, the heat sink 600 may be attached to a top surface of the first upper package 100 through a thermal interface material (TIM) layer 610. The heat sink 600 directly contacts the first upper package 100 through the TIM layer 610 so that heat dissipation characteristics may be improved.

The TIM layer 610 may include a thermally conductive and electrically insulating material. For example, the TIM layer 610 may include polymer containing metal powder such as silver (Ag) or Cu, thermal grease, white grease, or a combination thereof.

In some example embodiments, the heat sink 600 may have a flat plate shape. Accordingly, the heat sink 600 may be apart from a stiffener 300 in the vertical direction (Z direction). For example, when a vertical level of a top surface 100_U of the first upper package 100 is greater than a vertical level of the uppermost surface 300_A1_U of the stiffener 300, a bottom surface 600_B of the heat sink 600 attached to the top surface 100_U of the first upper package 100 may be apart from the stiffener 300. In some example embodiments, an air gap may be positioned in a space between the bottom surface 600_B of the heat sink 600 and a top surface 300_U of the stiffener 300.

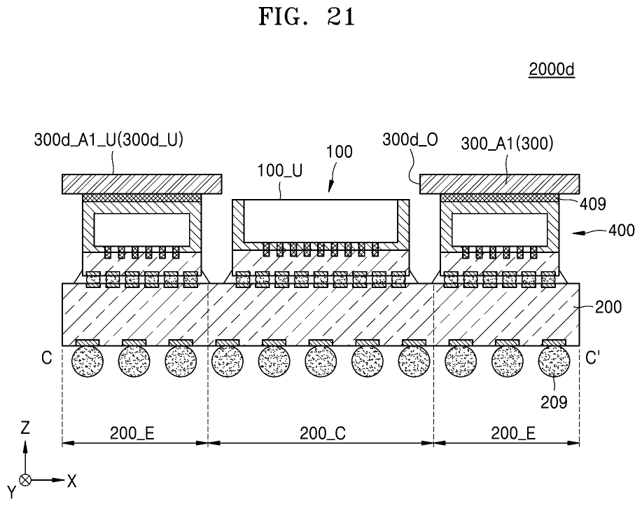

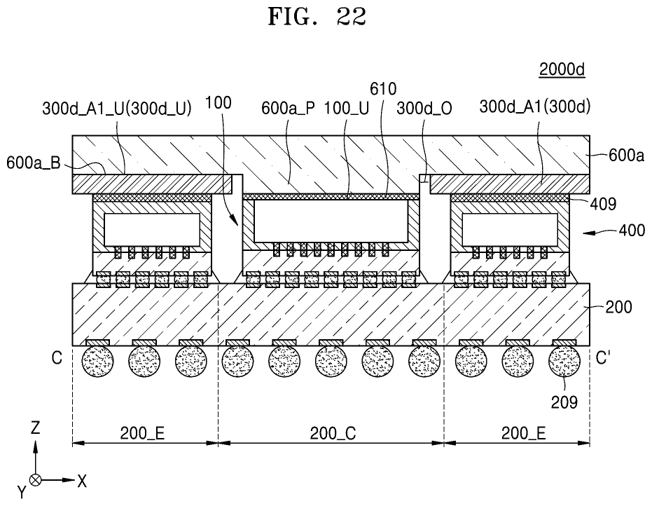

FIGS. 21 and 22 are cross-sectional views schematically illustrating semiconductor packages 2000d and 2000e according to some example embodiments, each taken along the line C-C′ of FIG. 15.

Most of components constituting the semiconductor packages 2000d and 2000e described below and materials forming the components are the same or substantially the same as or similar to those previously described in FIG. 14. Therefore, for convenience sake, differences between the semiconductor packages 2000d and 2000e of FIGS. 21 and 22 and the semiconductor package 2000 of FIG. 14 described above will be mainly described.

Referring to FIG. 21, the uppermost surface 300d_A1_U of a stiffener 300d of the semiconductor package 2000d may be at a vertical level different from a vertical level of a top surface 100_U of a first upper package 100. The uppermost surface 300d_A1_U of the stiffener 300d means a region of a top surface 300d_U of the stiffener 300d in which separation units 300d_A1 are positioned.

The uppermost surface 300d_A1_U of the stiffener 300d may be at a vertical level higher than a vertical level of the top surface 100_U of the first upper package 100. That is, the first upper package 100 may not protrude from the top surface 300d_U of the stiffener 300d in the vertical direction. However, because the first upper package 100 is positioned in an opening 300d_O of the stiffener 300d, the top surface 100_U of the first upper package 100 may be exposed to the outside.

In some example embodiments, the vertical level of the top surface 100_U of the first upper package 100 may be lower than a vertical level of the uppermost surface 300d_A1_U of the stiffener 300d and may be higher than a vertical level of a top surface of each of a plurality of second upper packages 400. However, the inventive concepts are not limited thereto, and the vertical level of the top surface 100_U of the first upper package 100 may be lower than the vertical level of the top surface of each of the plurality of second upper packages 400.

Referring to FIG. 22, the semiconductor package 2000e may further include a heat sink 600a. The heat sink 600a may dissipate heat generated by a semiconductor chip. The heat sink 600a may include a thermally conductive material having high thermal conductivity.

The heat sink 600a may be attached to a first upper package 100. For example, the heat sink 600a may be attached to a top surface 100_U of the first upper package 100 through a TIM layer 610. In some example embodiments, the heat sink 600a may be attached to separation units 300d_A1 of a stiffener 300d through the TIM layer 610. The heat sink 600a directly contacts the first upper package 100 through the TIM layer 610 so that heat dissipation characteristics may be improved.

The heat sink 600a may include a protrusion unit (e.g., member) 600a_P. The protrusion unit 600a_P of the heat sink 600a may protrude outward from a part of a bottom surface 600a_B of the heat sink 600a. The protrusion unit 600a_P of the heat sink 600a may correspond to an opening 300d_O of the stiffener 300d.

For example, when a vertical level of the uppermost surface 300d_A1_U of the stiffener 300d is greater than a vertical level of the top surface 100_U of the first upper package 100, the protrusion unit 600a_P may be positioned in the opening 300d_O of the stiffener 300d. Accordingly, the protrusion unit 600a_P of the heat sink 600a may contact the first upper package 100. For example, the TIM layer 610 may be positioned on a bottom surface of the protrusion unit 600a_P of the heat sink 600a so that the heat sink 600a may be attached to the first upper package 100.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
an upper package including a first package substrate, a first semiconductor chip on the first package substrate, and a first molding layer surrounding the first semiconductor chip;
a printed circuit board (PCB), the upper package being in a central region of the PCB; and
a stiffener on a top surface of the PCB, the stiffener including an opening,
wherein the top surface of the PCB contacts a bottom surface of the stiffener in at least part of edge regions of the PCB,
wherein, in the central region of the PCB and in edge regions other than the part of edge regions of the PCB contacting the stiffener, the top surface of the PCB is apart from the bottom surface of the stiffener in a vertical direction, and
wherein the opening of the stiffener overlaps the upper package in the vertical direction.

2. The semiconductor package of claim 1, wherein, in corner regions of the edge regions of the PCB, the top surface of the PCB contacts the bottom surface of the stiffener.

3. The semiconductor package of claim 1, wherein, between corner regions of the edge regions of the PCB, the top surface of the PCB contacts the bottom surface of the stiffener.

4. The semiconductor package of claim 1, wherein a region in which the bottom surface of the stiffener contacts the top surface of the PCB is point symmetrical with respect to a central point of the top surface of the PCB.

5. The semiconductor package of claim 1,
wherein the stiffener comprises a contact member contacting the top surface of the PCB, a separation member apart from the top surface of the PCB, and an extension member connecting the contact member to the separation member, and
wherein the contact member and the separation member of the stiffener are parallel to the top surface of the PCB.

6. The semiconductor package of claim 5, wherein the extension member is inclined in the vertical direction with respect to the top surface of the PCB.

7. The semiconductor package of claim 5, wherein
the stiffener comprises a plurality of contact members including the contact member, and
a distance between the contact members of the stiffener in a first horizontal direction is different from a distance between the contact member of the stiffener in a second horizontal direction perpendicular to the first horizontal direction.

8. The semiconductor package of claim 1,
wherein the first molding layer of the upper package covers a top surface of the first package substrate of the upper package and surrounds side surfaces of the first semiconductor chip of the upper package, and
wherein a top surface of the first semiconductor chip of the upper package and a top surface of the first molding layer are coplanar.

9. The semiconductor package of claim 1, wherein an area of the opening defined by the stiffener is greater than an area of the upper package.

10. The semiconductor package of claim 9, wherein one side of the stiffener defining the opening is apart from one side of the upper package by 2 mm to 5 mm in a horizontal direction.

11. The semiconductor package of claim 1,
wherein a pitch between each two of a plurality of lower connection pads of the first semiconductor chip is less than a pitch between each two of a plurality of lower connection terminals of the first package substrate, and
wherein the pitch between each two of the plurality of lower connection terminals of the first package substrate is less than a pitch between each two of a plurality of lower connection terminals of the PCB.

12. The semiconductor package of claim 1,
further comprising a plurality of passive elements on the PCB,
wherein the plurality of passive elements are in a region of the top surface of the PCB that is apart from the bottom surface of the stiffener in the vertical direction.

13. The semiconductor package of claim 1,
further comprising a plurality of passive elements,
wherein the plurality of passive elements are on at least one of a bottom surface of the first package substrate of the upper package and a bottom surface of the PCB.

14. A semiconductor package comprising:
a first upper package including a first package substrate, a first semiconductor chip on the first package substrate, and a first molding layer surrounding the first semiconductor chip;
a plurality of second upper packages each including a second package substrate, a second semiconductor chip on the second package substrate, and a second molding layer surrounding the second semiconductor chip;
a printed circuit board (PCB), the first upper package being on a central region of the PCB, and the PCB electrically connects the first upper package to the plurality of second upper packages; and
a stiffener on a top surface of the PCB, the stiffener including an opening,
wherein at least some part of edge regions of the PCB contact the stiffener,
wherein the central region of the PCB and edge regions other than the part of edge regions of the PCB contacting the stiffener are apart from the stiffener in a vertical direction, and
wherein the opening of the stiffener overlaps the first upper package in the vertical direction.

15. The semiconductor package of claim 14,
wherein a top surface of the first molding layer of the first upper package and a top surface of the first semiconductor chip are coplanar, and
wherein the second molding layer of each of the plurality of second upper packages covers a top surface of the second semiconductor chip.

16. The semiconductor package of claim 14, wherein the plurality of second upper packages are apart from the first upper package in a horizontal direction and the plurality of second upper packages are on a region of the top surface of the PCB that is apart from the stiffener in the vertical direction.

17. The semiconductor package of claim 14,
further comprising a heat sink,
wherein a vertical level of a top surface of the first upper package is higher than a vertical level of an uppermost surface of the stiffener, and
wherein the heat sink contacts a top surface of the first upper package and is apart from the uppermost surface of the stiffener in the vertical direction.

18. The semiconductor package of claim 14,
further comprising a heat sink including a protrusion member,
wherein a vertical level of a top surface of the first upper package is lower than a vertical level of an uppermost surface of the stiffener, and
wherein the protrusion member of the heat sink protrudes toward the opening of the stiffener and contacts the first upper package.

19. A semiconductor package comprising:
a first upper package including a first package substrate, a first semiconductor chip on the first package substrate, and a first molding layer surrounding side surfaces of the first semiconductor chip, the first semiconductor chip having a horizontal area less than a horizontal area of the first package substrate;
a printed circuit board (PCB), the first upper package being on a central region of the PCB, and the PCB having a horizontal area greater than a horizontal area of the first upper package; and
a stiffener attached to a top surface of the PCB by an adhesive layer, the stiffener including an opening,
wherein a pitch between each two of a plurality of lower connection pads of the first semiconductor chip is less than a pitch between each two of a plurality of lower connection terminals of the first package substrate,
wherein the pitch between each two of the plurality of lower connection terminals of the first package substrate is less than a pitch between each two of a plurality of lower connection terminals of the PCB,
wherein the top surface of the PCB contacts a bottom surface of the stiffener in at least part of edge regions of the PCB,
wherein, in the central region of the PCB and in edge regions other than the part of edge regions of the PCB contacting the stiffener, the top surface of the PCB is apart from the bottom surface of the stiffener in a vertical direction, and
wherein the opening of the stiffener overlaps the first upper package in the vertical direction.

20. The semiconductor package of claim 19, further comprising:
a plurality of second upper packages each including a second package substrate on the PCB, a second semiconductor chip on the second package substrate, and a second molding layer surrounding the second semiconductor chip, the second semiconductor having a horizontal area less than a horizontal area of the second package substrate; and
a plurality of passive elements on the PCB, the plurality of passive elements being electrically connected to the first upper package,
wherein each of the plurality of second upper packages and the plurality of passive elements are on a region of the top surface of the PCB that is apart from the stiffener.
